(19) United States
(12) Patent Application Publication
(10) Pub. No.: US 2008/0085014 A1
(43) Pub. Date: Apr. 10, 2008

(54) Active gain adjusting method and related system based on distance from users

(76) Inventors: Hung-Yi Chen, Hsin-Chu City (TW); Wei-Nan William Tseng, Taipei City (TW); Cheng-Te Tseng, Taipei City (TW); Yen-Ju Huang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,582

(22) Filed: Feb. 13, 2006

(51) Int. Cl. H03G 3/00

(52) U.S. Cl. 381/105

(57) ABSTRACT

A gain adjusting system for adjusting a gain of a sound signal in an audio system, includes a first detecting unit for capturing images of one or more faces of users and determining the number of faces and the size of the faces present in the images; a controller for receiving face data from the first detecting unit for comparing the sizes of faces in subsequently captured images with an initial face size and accordingly deciding and outputting a first decision signal; and a gain regulator coupled to the controller for adjusting the gain level of the sound signal according to the first decision signal.

### BACKGROUND OF THE INVENTION

1. Field of the Invention

The present invention relates to a gain adjusting system, and more specifically, to an active gain adjusting system for a speaker or microphone which adjusts the gain according to an estimated distance between the users and the speaker or microphone.

2. Description of the Prior Art

Conventionally, speaker volume and microphone gain are passively controlled. That is, the volume of the speaker and the gain of the microphone are adjusted when users feel like they should be changed. Users need to utilize a remote control or push buttons on an audio device for adjusting the speaker volume. However, having to manually change the speaker volume is not a convenient or friendly man-machine interface. Similarly, it is not convenient to have to manually adjust microphone gain if the users change their distance from the microphone.

### SUMMARY OF THE INVENTION

It is therefore an objective of the claimed invention to provide gain adjusting systems and related methods in order to solve the above-mentioned problems.

According to an embodiment of the present invention, a gain adjusting system for adjusting a gain of a sound signal in an audio system, includes a first detecting unit for capturing images of one or more faces of users and determining the number of faces and the size of the faces present in the images; a controller for receiving face data from the first detecting unit for comparing the sizes of faces in subsequently captured images with an initial face size and accordingly deciding and outputting a first decision signal; and a gain regulator coupled to the controller for adjusting the gain level of the sound signal according to the first decision signal.

According to another embodiment of the present invention, a gain adjusting system for adjusting a gain of a sound signal in an audio system includes a first detecting unit coupled to the controller, the first detecting unit detecting a reflected signal reflected from a user and outputting the reflected signal; a controller for receiving the reflected signal from the first detecting unit and accordingly deciding and outputting a first decision signal; and a gain regulator coupled to the controller for adjusting the gain level of the sound signal according to the first decision signal.

According to yet another embodiment of the present invention, a method of adjusting a gain of a sound signal in an audio system includes capturing images of one or more faces of users and determining the number of faces and the size of the faces present in the images; comparing the sizes of faces in subsequently captured images with an initial face size and accordingly deciding and outputting a first decision signal; and adjusting the gain level of the sound signal according to the first decision signal.

According to still another embodiment of the present invention, a method of adjusting a gain of a sound signal in an audio system includes detecting a reflected signal reflected from a user; deciding and outputting a first decision signal according to the reflected signal; and adjusting the gain level of the sound signal according to the first decision signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a gain adjusting system according to the present invention.

FIG. 2 is a flowchart summarizing a method of adjusting the gain according to the present invention.

### DETAILED DESCRIPTION

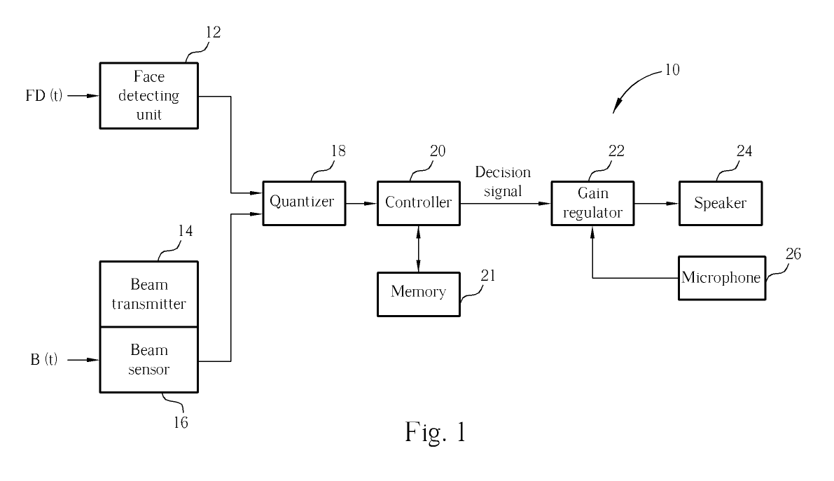

Please refer to FIG. 1. FIG. 1 is a functional block diagram of a gain adjusting system 10 according to the present invention. The gain adjusting system 10 receives two different kinds of input for determining how to adjust the gain output (volume) of a speaker 24 or the gain input of a microphone 26. A face detecting unit 12 receives a face detecting signal FD(t) containing images of one or more faces of users near the object in use, whether it is the speaker 24 or the microphone 26. The face detecting unit 12 analyzes the images and determines how many faces are captured and the image size of the captured faces. In general, the larger the face appears in the image, the closer the face is to the object in use, and vice versa. Face detection refers to determining the presence and the location of a face in an image by distinguishing the face from all other patterns in the scene. Most approaches exploit the temporal correlation between successive frames in order to refine the localization of the target. As will be explained below, the size of the faces detected by the face detecting unit 12 can be used to estimate an overall distance between the user(s) and the object in use.

In addition, a beam sensor 16 receives a beam signal B(t). A beam transmitter 14 constantly emits electromagnetic beams, and the beam signal B(t) represents the beams that are reflected back to the beam sensor 16 when the beams are obstructed by an object. For example, the beam transmitter 14 and the beam sensor 16 can utilize infrared beams, ultrasonic beams, laser beams, microwave beams, or other similar types of electromagnetic beams. The beam sensor is used to roughly estimate the distance between a user and the object in use. After receiving the reflected signal B(t), the beam sensor 16 needs to analyze the signal strength. Consequently, a rough distance between the user and the object in use is estimated.

The present invention makes use of both face detection and beam sensing to adaptively adjust the gain of the object in use. The face detecting unit 12 is set as the default mechanism to evaluate the gain. When certain conditions are met, the beam sensor 16 is instead the mechanism used to determine the gain.

The face detecting unit 12 outputs the number of faces detected and the size of the detected faces to a quantizer 18. In addition, the quantizer 18 also receives the beam signal strength output from the beam sensor 16. The quantizer 18 quantizes the face data and/or the beam data and outputs the quantized data to a controller 20. The quantizer 18 can be either a uniform quantizer or a non-uniform quantizer.

The controller 20 utilizes the data from the face detecting unit 12 and/or the beam sensor 16 to determine how the gain should be adjusted, as will be explained below. The controller 20 uses this data to estimate the overall distance between the users and the object in use, and outputs a decision signal to a gain regulator 22. The gain regulator 22 then adjusts the gain of the object in use according to the decision signal.

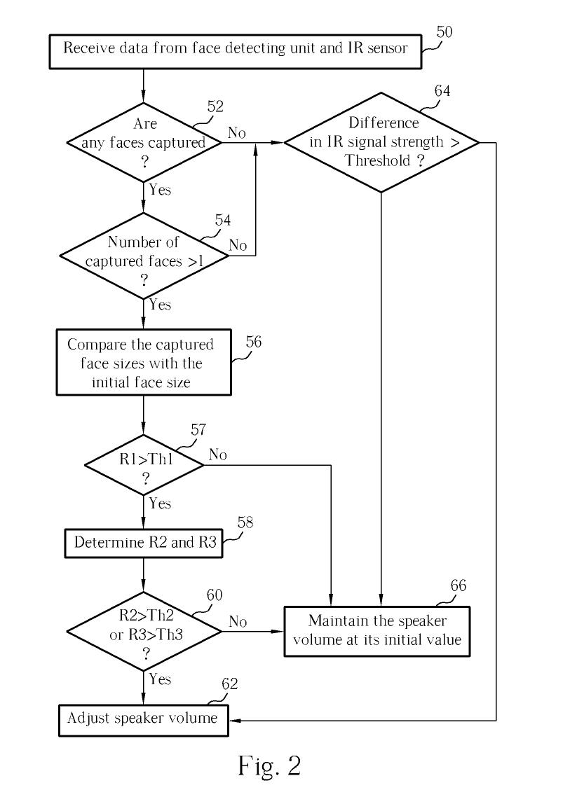

A flowchart summarizing a method of adjusting the gain according to the present invention is illustrated in FIG. 2. Initially, the gain is set when the system powers on. At this time, an initial face size is also calculated of all the users when the system is powered on, and an initial beam strength is recorded. All of these initial parameters are stored in a memory 21 accessed by the controller 20.

In step 50, the controller 20 receives data from the face detecting unit 12 and the beam sensor 16. In step 52, the controller 20 analyzes the face data provided by the face detecting unit 12 to determine if any faces have been captured. If so, the controller 20 determines if number of faces captured by the face detector is greater than a predetermined value. If yes, the controller uses the face data from the face detector and ignores the data from bean sensor. In this embodiment, the predetermined value is set to be one. That is, when more than one face has been captured, the data from the beam sensor 16 is ignored and the face data is instead used to determine the decision signal according to a calculated result which will be described below.

In step 56 the controller 20 compares the current size of the faces with the initial face size calculated when the system is powered on. The face size data is used to generate a first ratio R1 in step 57, where RI is a ratio of the number of face sizes that are different from the initial face sizes to the total number of faces. R1 represents that some of the users detected by the face detector have moved away or closer from the speaker/microphone since the time the system was powered on. If R1 is less than a threshold value, the gain does not have to be adjusted. That means minor part of the users has been moved so the system will not be adjusted. On the other hand, if the number of face sizes that have changed is greater than a first threshold value, two ratios are calculated in step 58. R2 represents the ratio of the number of faces that are smaller than the initial face size to the total number of detected faces. A higher value of R2 represents that more users have moved farther away from the speaker/microphone since it was powered on. Another ratio R3 represents the ratio of the number of faces that are larger than the initial face size to the total number of detected faces. A higher value of R3 represents that more users have moved closer to the speaker/microphone since it was powered on. R2 and R3 are initially equal to zero when the system is powered on since the initial face size is computed at this time and users have not had a chance to move closer to or farther from the object in use.

In step 60, both R2 and R3 are compared to respective second and third threshold values. If either R2 is greater than the second threshold or if R3 is greater than the third threshold value, the gain is adjusted in step 62. If R2 is greater than the second threshold, the gain should be increased since most of the users have moved farther from the object in use. On the other hand, if R3 is greater than the third threshold, the gain should be decreased since most of the users have moved closer to the object in use. If neither R2 nor R3 are greater than their respective threshold values, the gain is maintained at its initial value in step 66.

Back to the decision signal output from the controller 20, in the embodiment above, the decision signal is determined according to either R2 or R3 and the compared results with the threshold values. That is, if R2 is greater than the second threshold, the decision signal will be indicative of increasing the gain; if R3 is greater than the third threshold, the decision signal will be indicative of decreasing the gain.

If during steps 52 and 54 it is determined that no faces were captured or that only one face was captured, step 64 is instead executed for comparing the strength of the beam signal to a beam threshold value to estimate an overall distance of the users from the speaker/microphone. If the strength of the beam signal has changed from the initial beam signal strength by more than the beam threshold value, then the gain is adjusted accordingly in step 62. If the beam signal has become weaker than the initial bean signal, the gain is increased since this indicates that the user has moved farther away. On the other hand, if the beam signal has become stronger, the gain should be decreased since the user has moved closer to the object in use. If the beam signal strength is still close to the initial beam signal strength, then the gain is maintained at its initial value in step 66.

Decision signal in the embodiment above is determined according to the beam signals and the compared results with the threshold values. That is, if the beam signal is weaker than the initial bean signal, the decision signal is indicative of increasing the gain; if the beam is stronger, the decision signal is indicative of decreasing the gain.

The threshold values mentioned above can be set by various ways. Users can set the thresholds to adjust their speaker volume or microphone gains based on personal preferences. Also, these thresholds can be set by computer based on average human hearing.

In summary, the present invention gain adjusting system 10 and related adjusting method free the users from having to manually adjust the gain of the object in use. Instead, the controller 20 automatically adjusts the gain according to the distance that the users are from the object in use. Both face detection and beam signal strength measurements can be used to ensure that the distance between the users and the object in use is estimated accurately in different kinds of situations.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A gain adjusting system for adjusting a gain of a sound signal in an audio system, the gain adjusting system comprising:
a first detecting unit for capturing images of one or more faces of users and determining the number of faces and the size of the faces present in the images;
a controller for receiving face data from the first detecting unit for comparing the sizes of faces in subsequently captured images with an initial face size and accordingly deciding and outputting a first decision signal; and
a gain regulator coupled to the controller for adjusting the gain level of the sound signal according to the first decision signal.

2. The gain adjusting system of claim 1, wherein the controller generates the first decision signal when the number of faces is greater than a predetermined value.

3. The gain adjusting system of claim 1, further comprising a second detecting unit coupled to the controller, the second detecting unit detecting a reflected signal reflected from the user and outputting the reflected signal to the controller.

4. The gain adjusting system of claim 3, wherein the controller receives the strength of the reflected signal to estimate an overall user distance when the number of faces captured by the first detecting unit is less than a predetermined value.

5. The gain adjusting system of claim 4, wherein the controller utilizes the reflected signal to estimate the overall user distance when the number of faces captured by the first detecting unit is less than two.

6. The gain adjusting system of claim 4, wherein the controller decides a second decision signal according to the estimated overall user distance and outputs the second decision signal to the gain regulator for adjusting the gain level of the sound signals accordingly.

7. The gain adjusting system of claim 6, further comprising a memory unit for recording an initial user distance, wherein the controller further compares the estimated overall user distance with the initial user distance.

8. The gain adjusting system of claim 7, wherein if the estimated overall user distance is greater than the initial user distance, the controller decides the second decision signal to be indicative of increasing the gain level of the sound signal, if the estimated overall user distance is smaller than the initial user distance, the controller decides the second decision signal to be indicative of decreasing the gain level of the sound signal.

9. The gain adjusting system of claim 3, wherein the second detecting unit comprises:
an infrared transmitter for outputting infrared signals; and
an infrared sensor for measuring the strength of reflected signals of the infrared signals reflected back toward the infrared sensor.

10. The gain adjusting system of claim 3, wherein the second detecting unit comprises:
an ultrasonic transmitter for outputting ultrasonic signals; and
an ultrasonic sensor for measuring the strength of reflected signals of the ultrasonic signals reflected back toward the ultrasonic sensor.

11. The gain adjusting system of claim 3, wherein the second detecting unit comprises:
a laser transmitter for outputting laser signals; and
a laser sensor for measuring the strength of reflected signals of the laser signals reflected back toward the laser sensor.

12. The gain adjusting system of claim 3, wherein the second detecting unit comprises:
a microwave transmitter for outputting microwave signals; and
a microwave sensor for measuring the strength of reflected signals of the microwave signals reflected back toward the microwave sensor.

13. The system of claim 1, further comprising a quantizer for quantizing the number of captured faces and their corresponding face sizes according to the images captured by the first detecting unit.

14. The gain adjusting system of claim 1, wherein the controller calculates a first ratio, the first ratio being a ratio of the number of face sizes different from the initial face size to the total number of faces.

15. The gain adjusting system of claim 14, wherein if the first ratio is greater than a first threshold value, the controller further calculates a second ratio, the second ratio being a ratio of the number of sizes of faces smaller than the initial face size to the total number of faces, and decides the first decision signal to be indicative of increasing the gain level if the second ratio is greater than a second threshold value.

16. The gain adjusting system of claim 14, wherein if the first ratio is smaller than the first threshold value, the controller further calculates a third ratio, the third ratio being a ratio of the number of sizes of faces larger than the initial face size to the total number of faces, and decides the first decision signal to be indicative of decreasing the gain level if the third ratio is greater than a third threshold value.

17. The gain adjusting system of claim 14, wherein if the first ratio is zero, the controller decides the first decision signal to be indicative of maintaining the gain level.

18. The gain adjusting system of claim 1, wherein adjusting the gain level of the sound signal comprises adjusting a gain level of a sound signal output by a speaker.

19. The gain adjusting system of claim 1, wherein adjusting the gain level of the sound signal comprises adjusting a gain level of a sound signal received through a microphone.

20. A gain adjusting system for adjusting a gain of a sound signal in an audio system, the gain adjusting system comprising:
a first detecting unit coupled to the controller, the first detecting unit detecting a reflected signal reflected from a user and outputting the reflected signal;
a controller for receiving the reflected signal from the first detecting unit and accordingly deciding and outputting a first decision signal; and
a gain regulator coupled to the controller for adjusting the gain level of the sound signal according to the first decision signal.

21. The gain adjusting system of claim 20, wherein the controller receives the strength of the reflected signal to estimate an overall user distance, decides the first decision signal according to the estimated overall user distance, and outputs the first decision signal to the gain regulator for adjusting the gain level of the sound signals accordingly.

22. The gain adjusting system of claim 21, further comprising a memory unit for recording an initial user distance, wherein the controller further compares the estimated overall user distance with the initial user distance.

23. The gain adjusting system of claim 22, wherein if the estimated overall user distance is greater than the initial user distance, the controller decides the first decision signal to be indicative of increasing the gain level of the sound signal, if the estimated overall user distance is smaller than the initial user distance, the controller decides the first decision signal to be indicative of decreasing the gain level of the sound signal.

24. The gain adjusting system of claim 20, wherein the first detecting unit comprises:
an infrared transmitter for outputting infrared signals; and
an infrared sensor for measuring the strength of reflected signals of the infrared signals reflected back toward the infrared sensor.

25. The gain adjusting system of claim 20, wherein the first detecting unit comprises:
an ultrasonic transmitter for outputting ultrasonic signals; and
an ultrasonic sensor for measuring the strength of reflected signals of the ultrasonic signals reflected back toward the ultrasonic sensor.

26. The gain adjusting system of claim 20, wherein the first detecting unit comprises:
a laser transmitter for outputting laser signals; and
a laser sensor for measuring the strength of reflected signals of the laser signals reflected back toward the laser sensor.

27. The gain adjusting system of claim 20, wherein the first detecting unit comprises:
a microwave transmitter for outputting microwave signals; and
a microwave sensor for measuring the strength of reflected signals of the microwave signals reflected back toward the microwave sensor.

28. The gain adjusting system of claim 20, further comprising a second detecting unit coupled to the controller, the second detecting unit capturing images of one or more faces of users and determining the number of faces and the size of the faces present in the images and outputting the face data to the controller, and the controller deciding and outputting a second decision signal according to the received face data.

29. The gain adjusting system of claim 28, wherein the controller receives the strength of the reflected signal to estimate the overall user distance when the number of faces captured by the second detecting unit is less than a predetermined value.

30. The gain adjusting system of claim 29, wherein the controller utilizes the reflected signal to estimate the overall user distance when the number of faces captured by the second detecting unit is less than two.

31. The system of claim 28, further comprising a quantizer for quantizing the number of captured faces and their corresponding face sizes according to the images captured by the second detecting unit.

32. The gain adjusting system of claim 28, wherein the controller calculates a first ratio, the first ratio being a ratio of the number of face sizes different from the initial face size to the total number of faces.

33. The gain adjusting system of claim 32, wherein if the first ratio is greater than a first threshold value, the controller further calculates a second ratio, the second ratio being a ratio of the number of sizes of faces smaller than the initial face size to the total number of faces, and decides the second decision signal to be indicative of increasing the gain level if the second ratio is greater than a second threshold value.

34. The gain adjusting system of claim 32, wherein if the first ratio is smaller than the first threshold value, the controller further calculates a third ratio, the third ratio being a ratio of the number of sizes of faces larger than the initial face size to the total number of faces, and decides the second decision signal to be indicative of decreasing the gain level if the third ratio is greater than a third threshold value.

35. The gain adjusting system of claim 32, wherein if the first ratio is zero, the controller decides the second decision signal to be indicative of maintaining the gain level.

36. The gain adjusting system of claim 20, wherein adjusting the gain level of the sound signal comprises adjusting a gain level of a sound signal output by a speaker.

37. The gain adjusting system of claim 20, wherein adjusting the gain level of the sound signal comprises adjusting a gain level of a sound signal received through a microphone.

38. A method of adjusting a gain of a sound signal in an audio system, the method comprising:
capturing images of one or more faces of users and determining the number of faces and the size of the faces present in the images;
comparing the sizes of faces in subsequently captured images with an initial face size and accordingly deciding and outputting a first decision signal; and
adjusting the gain level of the sound signal according to the first decision signal.

39. The method of claim 38, further comprising detecting a reflected signal reflected from the user.

40. The method of claim 39, further comprising utilizing the strength of the reflected signal to estimate an overall user distance when the number of faces captured is less than a predetermined value.

41. The method of claim 40, further comprising utilizing the reflected signal to estimate the overall user distance when the number of faces captured is less than two.

42. The method of claim 40, further comprising:
deciding a second decision signal according to the estimated overall user distance; and
adjusting the gain level of the sound signals according to the second decision signal.

43. The method of claim 42, further comprising:
recording an initial user distance; and
comparing the estimated overall user distance with the initial user distance.

44. The method of claim 43, further comprising:
deciding the second decision signal to be indicative of increasing the gain level of the sound signal if the estimated overall user distance is greater than the initial user distance; and
deciding the second decision signal to be indicative of decreasing the gain level of the sound signal if the estimated overall user distance is smaller than the initial user distance.

45. The method of claim 39, wherein detecting the reflected signal reflected from the user comprises:
outputting infrared signals; and
measuring the strength of reflected signals of the infrared signals reflected back toward the infrared sensor.

46. The method of claim 38, further comprising quantizing the number of captured faces and their corresponding face sizes according to the captured images.

47. The method of claim 38, wherein comparing the sizes of faces in subsequently captured images with the initial face size comprises calculating a first ratio, the first ratio being a ratio of the number of face sizes different from the initial face size to the total number of faces.

48. The method of claim 47, further comprising:
calculating a second ratio if the first ratio is greater than a first threshold value, the second ratio being a ratio of the number of sizes of faces smaller than the initial face size to the total number of faces; and
deciding the first decision signal to be indicative of increasing the gain level if the second ratio is greater than a second threshold value.

49. The method of claim 47, further comprising:
calculating a third ratio if the first ratio is smaller than the first threshold value, the third ratio being a ratio of the number of sizes of faces larger than the initial face size to the total number of faces; and
deciding the first decision signal to be indicative of decreasing the gain level if the third ratio is greater than a third threshold value.

50. The method of claim 47, further comprising deciding the first decision signal to be indicative of maintaining the gain level if the first ratio is zero.
